(19) United States
(12) Patent Application Publication
(10) Pub. No.: US 2025/0218762 A1
(43) Pub. Date: Jul. 3, 2025

(54) SUBSTRATE PROCESSING APPARATUS AND SUBSTRATE PROCESSING METHOD

(71) Applicant: SEMES CO., LTD., Cheonan-si (KR)

(72) Inventors: Hye Bin GWON, Cheonan-si (KR); Do Hyeon YOON, Cheonan-si (KR); Mi So PARK, Cheonan-si (KR); Yong Joon IM, Yongin-si (KR)

(73) Assignee: SEMES CO., LTD., Cheonan-si (KR)

(21) Appl. No.: 19/005,286

(22) Filed: Dec. 30, 2024

(30) Foreign Application Priority Data
Dec. 29, 2023 (KR) 10-2023-0197555

(51) Int. Cl. H01L 21/02; H01L 21/67

(52) U.S. Cl. CPC H01L 21/02101; H01L 21/67034

(57) ABSTRACT

The present invention provides a substrate drying method and a substrate drying apparatus. The substrate drying method includes a pressurizing step, a processing step, and a depressurizing step, in which the pressurizing step includes a first supply step of supplying supercritical fluid at a first temperature and a second supply step of supplying, thereafter, the supercritical fluid at a second temperature higher than the first temperature. Thereafter, in the processing step, a substrate is processed with the supercritical fluid by supplying the supercritical fluid at a third temperature the same as or higher than the second temperature.

### CROSS-REFERENCE TO RELATED APPLICATIONS

This application claims priority to and the benefit of Korean Patent Application No. 10-2023-0197555 filed in the Korean Intellectual Property Office on Dec. 29, 2023, the entire contents of which are incorporated herein by reference.

### TECHNICAL FIELD

The present invention relates to an apparatus and method for processing a substrate and, in more detail, an apparatus and method for processing a substrate, the apparatus and method processing a substrate using supercritical fluid.

### BACKGROUND ART

A semiconductor device is manufactured through various processes including a deposition process that forms a circuit pattern on a substrate such as a silicon wafer, a photolithography process, and an etching process. Various foreign substances such as particles, organic contaminants, and metallic impurities are produced and remain on a wafer during this manufacturing process. These foreign substances cause defects in a substrate, thereby acting as factors that directly affect the yield of semiconductor devices. Accordingly, a semiconductor manufacturing process is necessarily accompanied with a cleaning process for removing such foreign substances.

In general, a cleaning process includes treatment liquid processing, rinse processing, and drying processing. Recently, drying processing is performed using supercritical fluid to prevent collapse of a pattern on a substrate during rinse processing.

General drying apparatuses pressurize a processing space to a set pressure by supplying supercritical fluid at a position lower than a substrate with the substrate loaded in the processing space in a high-pressure drying chamber, and supplies the supercritical fluid at a position higher than the substrate when the processing process reaches the set pressure, thereby processing a substrate.

The temperature of the supercritical fluid when the processing is pressurized in these apparatuses is higher than the temperature of the supercritical fluid when a substrate is processed. Accordingly, the density of the supercritical fluid in the processing step is lower than the density of the supercritical fluid that is supplied in the pressurizing step. Accordingly, when supercritical fluid starts to be supplied in the processing step, the efficiency of drying a substrate decreases due to the difference of density between the supercritical fluid remaining in a processing space and the supercritical fluid that starts to be supplied to the processing space.

### SUMMARY OF THE INVENTION

An object of the present invention is to provide an apparatus and method for processing a substrate, the apparatus and method being able to improve the processing efficiency when processing a substrate using supercritical fluid.

An object of the present invention is to provide an apparatus and method for processing a substrate, the apparatus and method being able to prevent poor drying by the difference of density due to variation of the temperature of supercritical fluid when drying a substrate using the supercritical fluid.

Objects of the present invention are not limited to the objects described above. Other objects not stated here may be clearly understood to those skilled in the art from the following description.

An exemplary embodiment of the present invention provides, a substrate processing method, comprising: a loading step of loading a substrate into a processing space; a pressurizing step of pressurizing the processing space to a first pressure by supplying supercritical fluid to the processing space after the loading step; a processing step of processing the substrate in the processing space by supplying the supercritical fluid to the processing space after the pressurizing step; a depressurizing step of depressurizing the processing space to a second pressure lower than the first pressure after the processing step; and an unloading step of unloading the substrate from the processing space after the depressurizing step, wherein the pressurizing step comprises: a first supply step of supplying the supercritical fluid at a first temperature to the processing space to a third pressure lower than the first pressure; and a second supply step of supplying the supercritical fluid at a second temperature higher than the first temperature to the processing space when the pressure of the processing space reaches the third pressure.

According to an embodiment of the present invention, in the processing step, the supercritical fluid may be supplied to the processing space at a third temperature higher than the first temperature.

According to an embodiment of the present invention, the third temperature may be the same as the second temperature.

According to an embodiment of the present invention, the third temperature may be higher than the second temperature.

According to an embodiment of the present invention, the third pressure may be higher than critical pressure of the supercritical fluid.

According to an embodiment of the present invention, a position of the supercritical fluid that is supplied to the processing space in the processing step and a position of the supercritical fluid that is supplied to the processing space in the pressurizing step may be different from each other.

According to an embodiment of the present invention, in the pressurizing step, the supercritical fluid may be supplied to the processing space at a position lower than the substrate disposed in the processing space.

According to an embodiment of the present invention, in the processing step, the supercritical fluid may be supplied to the processing space at a position higher than the substrate disposed in the processing space.

According to an embodiment of the present invention, the supercritical fluid may be carbon dioxide.

An exemplary embodiment of the present invention provides, a substrate processing apparatus, comprising: a body providing a processing space for processing a substrate; a supporting unit supporting the substrate in the processing space; a fluid supply unit supplying supercritical fluid to the processing space; an exhaust unit exhausting fluid in the processing space; and a control unit controlling the fluid supply unit, wherein the fluid supply unit comprises: a fluid supply line supplying supercritical fluid to the processing space from a fluid supplier; and a heating unit installed in the fluid supply line and heating the supercritical fluid, the control unit controls the fluid supply unit and the exhaust unit such that a pressurizing step of pressurizing the processing space to a first pressure by supplying supercritical fluid to the processing space when a substrate is loaded into the processing space, a processing step of processing the substrate in the processing space using the supercritical fluid supplied to the processing space after the pressurizing step, and a depressurizing step of depressurizing the processing space to a second pressure lower than the first pressure are sequentially performed, and the control unit controls the fluid supply unit such that a first supply step of supplying the supercritical fluid at a first temperature to the processing space to a third pressure lower than the first pressure in the pressurizing step, and a second supply step of supplying the supercritical fluid at a second temperature higher than the first temperature to the processing space when the pressure of the processing space reaches a set temperature are sequentially performed.

According to an embodiment of the present invention, the fluid supply line comprises: a main supply line that is connected to the fluid supplier and in which a main valve is installed; a first line that is connected to the main supply line, that supplies supercritical fluid to the processing space at a position lower than a substrate supported on the supporting unit in the processing space, and in which a first valve is installed; and a second line that is connected to the main supply line, that supplies supercritical fluid to the processing space at a position higher than a substrate supported on the supporting unit in the processing space, and in which a second valve is installed, and the control unit may be controls the fluid supply unit such that the supercritical fluid is supplied to the processing space through the first line in the first supply step and the second supply step.

According to an embodiment of the present invention, the heating unit comprises: a main heater installed in the main supply line; a first heater installed in the first line; and a second heater installed in the second line, and a bypass line that bypasses the first heater and in which a third valve is installed may be connected to the first line.

According to an embodiment of the present invention, the control unit may be controls the fluid supply unit such that the supercritical fluid is supplied to the processing space through the bypass line in the first supply step and the supercritical fluid is supplied to the processing space after being heated by the first heater in the second supply step.

According to an embodiment of the present invention, the control unit may be controls the fluid supply unit such that the second heater heats supercritical fluid to higher temperature than the first heater and the first heater heats supercritical fluid to higher temperature than the main heater.

According to an embodiment of the present invention, the control unit may be controls the fluid supply unit such that temperature of supercritical fluid that is supplied to the processing space in the processing step is higher than temperature of supercritical fluid that is supplied to the processing space in the first supply step.

According to an embodiment of the present invention, the control unit may be controls the main valve, the first valve, the second valve, and the third valve such that the supercritical fluid sequentially passes through the main supply line and the first line in the second supply step, and the control unit controls the first heater such that the supercritical fluid is supplied at the second temperature to the processing space.

According to an embodiment of the present invention, the control unit may be controls the main valve, the first valve, the second valve, and the third valve such that the supercritical fluid passes through the main supply line and the second line in the processing step, and the control unit controls the second heater such that the supercritical fluid is supplied at temperature the same as the second temperature to the processing space.

According to an embodiment of the present invention, the control unit may be controls the main valve, the first valve, the second valve, and the third valve such that the supercritical fluid passes through the main supply line and the second line in the processing step, and the control unit controls main heater and the second heater such that the supercritical fluid is supplied at temperature higher the second temperature to the processing space.

According to an embodiment of the present invention, wherein the supercritical fluid that is supplied by the fluid supply unit may be carbon dioxide.

An exemplary embodiment of the present invention provides, a substrate processing method, comprising: a liquid processing step of liquid-processing a substrate by supplying a processing liquid to the substrate in a liquid processing chamber; a transfer step of transferring the substrate into a drying chamber after the liquid processing step; and a drying step of drying the substrate using supercritical fluid in the drying chamber after the transferring step, wherein the drying step comprises: a loading step of loading a substrate into a processing space provided in the drying chamber; a pressurizing step of pressurizing the processing space to a first pressure by supplying supercritical fluid to the processing space after the loading step; a processing step of processing the substrate in the processing space using the supercritical fluid supplied to the processing space after the pressurizing step; a depressurizing step of depressurizing the processing space to a second pressure lower than the first pressure after the processing step; and an unloading step of unloading the substrate from the processing space after the depressurizing step, wherein the pressurizing step comprises a first supply step and a second supply step, wherein the pressurizing step comprises: a first supply step of supplying the supercritical fluid at a first temperature to the processing space at a height lower than the substrate to a third pressure lower than the first pressure; and a second supply step of supplying the supercritical fluid at a second temperature higher than the first temperature to the processing space at a height higher than the substrate when the pressure of the processing space reaches the third pressure, the supercritical fluid is supplied at a third temperature to processing space in the processing step, and the third temperature is higher than the first temperature and may be the same as or higher than the second temperature.

According to an embodiment of the present invention, it is possible to improve processing efficiency when processing a substrate with supercritical fluid.

Further, according to an embodiment of the present invention, it is possible to prevent generation of poor drying by a density difference due to change of temperature of supercritical fluid when drying a substrate using the supercritical fluid.

Effects of the present invention are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a plan view schematically showing a substrate processing apparatus according to an embodiment of the present invention.

FIG. 2 is a view schematically showing an embodiment of the liquid processing chamber of FIG. 1.

FIG. 3 is a view schematically showing an embodiment of the drying chamber of FIG. 2.

FIG. 4 is a view schematically showing an embodiment of a fluid supply unit.

FIG. 5 is a flowchart schematically showing a substrate processing process.

FIG. 6 is a graph showing the pressure and temperature in a drying chamber over time in a drying step according to an embodiment of the substrate processing apparatus.

FIG. 7 is a view schematically showing valves and the flow of fluid in a first supply step.

FIG. 8 is a view schematically showing valves and the flow of fluid in a second supply step.

FIG. 9 is a view schematically showing valves and the flow of fluid in a processing step.

FIG. 10 is a view schematically showing valves and the flow of fluid in a depressurizing step.

FIG. 11 to FIG. 13 are views schematically showing a modified example of the fluid supply unit of FIG. 4.

FIG. 14 is a view showing another example of the graph showing the pressure and temperature in a drying chamber over time in a drying step.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present invention may be modified in various ways and the scope of the present invention should not be construed as being limited to the embodiments to be described below. The embodiments are provided to more completely explain the present invention to those skilled in the art. Accordingly, the shapes of the components shown in the figures are exaggerated to enhance clearer description.

A substrate processing apparatus according to the present invention is described hereafter. A substrate in embodiments of the present invention may be a wafer that is used to manufacturing a semiconductor. However, unlike this, the substrate may be a glass substrate for manufacturing a flat display panel or another kind of substrate such as a mask that is used for pattern transfer in a photolithography process.

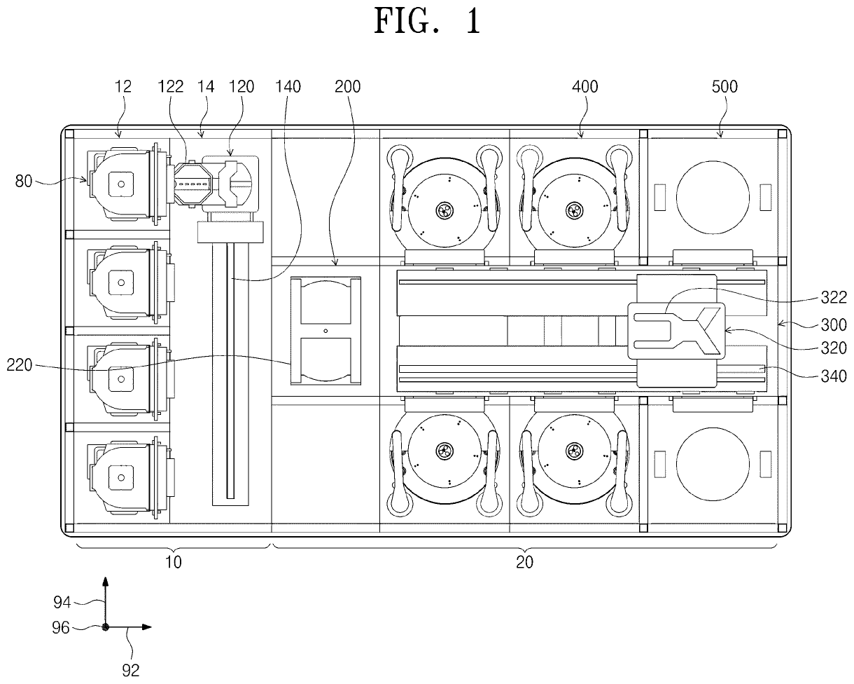

Referring to FIG. 1, a substrate processing apparatus includes an index module 10, a processing module 20, and a control unit 30. According to an embodiment, the index module 10 and the processing module 20 are disposed in one direction. Hereafter, the direction in which the index module 10 and the processing module 20 are arranged is referred to as a first direction 92, a direction perpendicular to the first direction 92 when seen from above is referred to as a second direction 94, and a direction perpendicular to both of the first direction 92 and the second direction 94 is referred to as a third direction 96.

The index module 10 transfers substrates W to the processing module 20 from containers 80 accommodating the substrates W and puts the substrates W processed at the processing module 20 into the containers 80. The longitudinal direction of the index module 10 is provided in the second direction 94. The index module 10 has a loadport 12 and an index frame 14. The loadport 12 is positioned at the opposite side to the processing module 20 with the index frame 14 therebetween. The containers 80 accommodating substrates W are placed in the loadport 12. The load port 12 may be provided in multiple instances and the plurality of load ports 12 may be disposed in the second direction 94.

The container 80 may be a container for sealing such as a Front Open Unified Pod (FOUP). The container 80 may be placed in the loadport 12 by a worker or a conveying device (not shown) such as an overhead transfer, an overhead conveyor, or an automatic guided vehicle.

An index robot 120 is provided at the index frame 14. A guide rail 140 of which the longitudinal direction is provided in the second direction 94 is provided in the index frame 14 and the index robot 120 may be provided to be movable on the guide rail 140. The index robot 120 includes a hand 122 on which substrates W are placed and the hand 122 may be provided to be able to move forward and backward, rotate about the third direction 96, and move in the third direction 96. The hand 122 may be provided in multiple instances to be spaced apart from each other in the up-down direction and the hands 122 can move forward and backward independently from each other.

The processing module 20 includes a buffer unit 200, a transfer chamber 300, a liquid processing chamber 400, and a drying chamber 500. The buffer unit 200 provides a space in which substrates W that are loaded into the processing module 20 and substrates W that are unloaded from the processing module 20 temporarily stay. The liquid processing chamber 400 performs a liquid processing process of performing liquid processing on substrates W by supplying liquid onto the substrates W. The drying chamber 500 can perform a drying process that removes liquid remaining on substrates W. The transfer chamber 300 transfers substrates W between the buffer unit 200, the liquid processing chamber 400, and the drying chamber 500.

The longitudinal direction of the transfer chamber 300 may be provided in the first direction 92. The buffer unit 200 may be disposed between the index module 10 and the transfer chamber 300. The liquid processing chamber 400 and the drying chamber 500 may be disposed on sides of the transfer frame 300. The liquid processing chamber 400 and the transfer chamber 300 may be disposed in the second direction 94. The drying chamber 500 and the transfer chamber 300 may be disposed in the second direction 94. The buffer unit 200 may be positioned at an end of the transfer chamber 300.

According to an embodiment, the liquid processing chambers 400 are disposed at both sides of the transfer chamber 300, the drying chambers 500 are disposed at both sides of the transfer chamber 300, and the liquid processing chambers 400 may be disposed at positions close to the buffer unit 200 in comparison to the drying chambers 500. The liquid processing chambers 400 may be provided in an array of A×B (A and B are each a natural number of 1 or more) in the first direction 92 and the third direction 96, respectively, at a side of the transfer chamber 300. The drying chambers 500 may be provided by the number of C×D (C and D are each a natural number of 1 or more) in the first direction 92 and the third direction 96, respectively, at a side of the transfer chamber 300. Unlike the above description, only the liquid processing chambers 400 may be provided at a side of the transfer chamber 300 and only the drying chambers 500 may be provided at another side.

The transfer chamber 300 has a transfer robot 320. A guide rail 340 of which the longitudinal direction is provided in the first direction 92 is provided in the transfer chamber 300 and the transfer robot 320 may be provided to be movable on the guide rail 340. The transfer robot 320 includes a hand 322 on which substrates W are placed and the hand 322 may be provided to be able to move forward and backward, rotate about the third direction 96, and move in the third direction 96. The hand 322 may be provided in multiple instances to be spaced apart from each other in the up-down direction and the hands 322 can move forward and backward independently from each other.

The buffer unit 200 has a plurality of buffers 220 on which substrates W are placed. The buffers 220 may be disposed to be spaced apart from each other in the third direction 96. The buffer unit 200 is open on the front face and the rear face. The front face is a surface that faces the index module 10 and the rear face is a surface that faces the transfer chamber 300. The index robot 120 can approach the buffer unit 200 through the front face and the transfer robot 320 can approach the buffer unit 200 through the rear face.

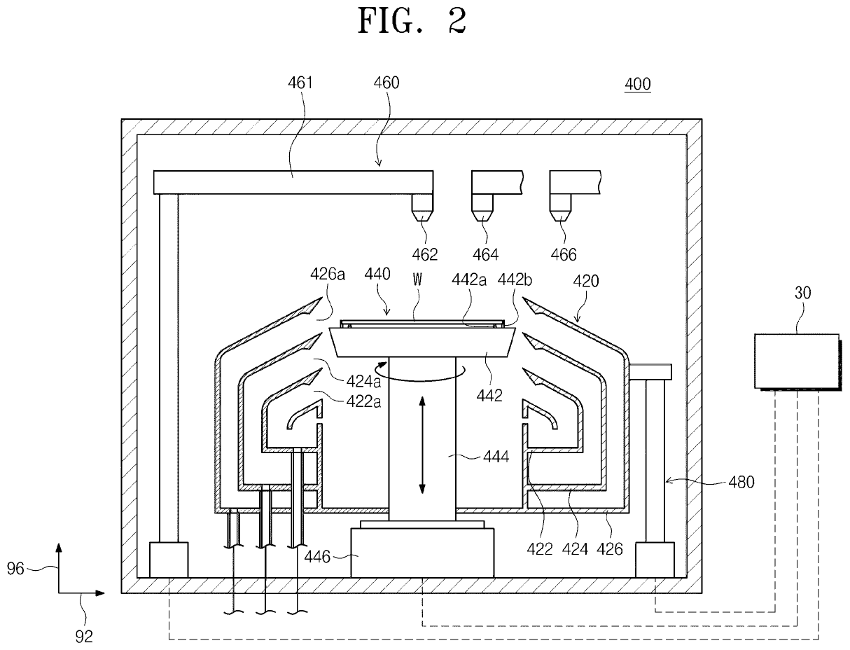

FIG. 2 is a view schematically showing an embodiment of the liquid processing chamber of FIG. 1.

Referring to FIG. 2, the liquid processing chamber 400 includes a housing 410, a cup 420, a supporting unit 440, a liquid supply unit 460, and an elevation unit 480. The housing 410 is provided substantially in a rectangular prism shape. The cup 420, the supporting unit 440, and the liquid supply unit 460 are disposed in the housing 410.

The cup 420 has a processing space with an open top and substrates W are liquid-processed in the processing space. The supporting unit 440 supports substrates W in the processing space. The liquid supply unit 460 supplies liquid to a substrate W supported on the supporting unit 440. A plurality of kinds of processing liquids is provided and may be sequentially supplied to a substrate W. The elevation unit 480 adjusts the relative height between the cup 420 and the supporting unit 440.

According to an example, the cup 420 has a plurality of recovery baths 422, 424, and 426. The recovery baths 422, 424, and 426 each have a recovery space for recovering liquid used to process a substrate. The recovery baths 422, 424, and 426 are each provided in a ring shape surrounding the supporting unit 440. The processing liquids splashed by rotation of a substrate W when the liquid processing process is performed flow into the recovery spaces through inlets 422a, 424a, and 426a of the recovery baths 422, 424, and 426, respectively. According to an example, the cup 420 has a first recovery bath 422, a second recovery bath 424, and a third recovery bath 426. The first recovery bath 422 is disposed to surround the supporting unit 440, the second recovery bath 424 is disposed to surround the first recovery bath 422, and the third recovery bath 426 is disposed to surround the second recovery bath 424. The second inlet 424a for supplying liquid into the second recovery bath 424 may be positioned higher than the first inlet 422a for supplying liquid into the first recovery bath 422, and the third inlet 426a for supplying liquid into the third recovery bath 426 may be positioned higher than the second inlet 424a.

The supporting unit 440 has a supporting plate 442 and an actuating shaft 444. The upper surface of the supporting plate 442 is provided substantially in a circular shape and may have a diameter larger than substrates W. Supporting pins 442a supporting the rear surface of a substrate W is provided at the center portion of the supporting plate 442 and are provided such that the upper ends thereof protrude from the supporting plate 442 to space a substrate W a predetermined distance from the supporting plate 442. Chuck pins 442b are provided on the edge portion of the supporting plate 442. The chuck pins 442b protrude upward from the supporting plate 442 and support the side of a substrate W to prevent the substrate W from separating from the supporting unit 440 when the substrate W is rotated. The actuating shaft 444 is driven by an actuator 446, is connected with the center of the underside of a substrate W, and rotates the supporting plate 442 about the center axis thereof.

According to an embodiment, the liquid supply unit 460 has a first nozzle 462, a second nozzle 464, and a third nozzle 466. The second nozzle 462 supplies a first liquid to substrates W. The first liquid may be liquid that removes a film or foreign substances remaining on a substrate W. The second nozzle 464 supplies a second liquid to substrates W. The second liquid may be liquid that is dissolved well in the third liquid. For example, the second liquid may be liquid that is dissolved well in the third liquid in comparison to the first liquid. The second liquid may be liquid that neutralizes the first liquid supplied to a substrate W. Further, the second liquid may be liquid that neutralizes the first liquid and is dissolved well in the third liquid in comparison to the first liquid. According to an example, the second liquid may be water. The third nozzle 466 supplies a third liquid to substrates W. The third liquid may be liquid that is dissolved well in supercritical fluid that is used in the drying chamber 500. For example, the third liquid may be liquid that is dissolved well in supercritical fluid that is used in the drying chamber 500. According to an example, the third liquid may be an organic solvent. The organic solvent may be isopropyl alcohol (IPA). The first nozzle 462, the second nozzle 464, and the third nozzle 466 are supported by different arms 461 and the arms 461 can be independently moved. Selectively, the first nozzle 462, the second nozzle 464, and the third nozzle 466 may be mounted on the same arm and moved simultaneously.

The elevation unit 480 moves the cup 420 in the up-down direction. The relative height between the cup 420 and a substrate W is changed by up-down movement of the cup 420. Accordingly, the recovery baths 422, 424, and 426 that recover processing liquids are changed, depending on the kinds of processing liquids that are supplied to substrates W, so it is possible to separately recover processing liquids. Unlike the above description, the cup 420 may be fixed and the elevation unit 480 may move the supporting unit 440 in the up-down direction.

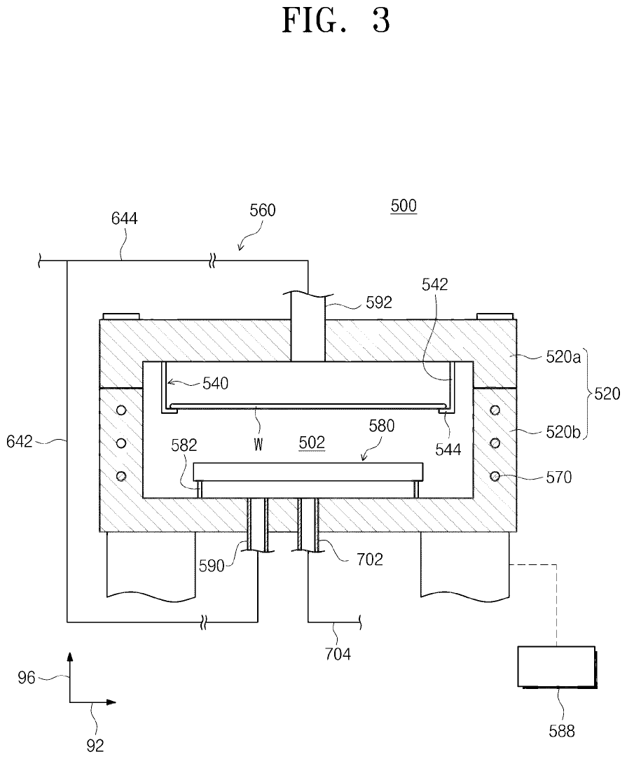

FIG. 3 is a view schematically showing an embodiment of the drying chamber of FIG. 2.

According to an embodiment, the drying chamber 500 removes liquid on substrates W using supercritical fluid. The drying chamber 500 has a body 520, a supporting unit 540, a fluid supply unit 560, an exhaust unit 700, and a filler 580.

The body 520 provides a processing space 502 in which the drying process is performed. The body 520 has an upper body 520a and a lower body 520b, and the upper body 520a and the lower body 520b provide the processing space 502 by combining with each other. The upper body 520a is provided over the lower body 520b. The position of the upper body 520a may be fixed and the lower body 520b may be moved up and down by an actuating member 588 such as a cylinder. When the lower body 520b is spaced from the upper body 522a, the processing space 502 is opened and a substrate W is loaded or unloaded. When a process is performed, the lower body 520b comes in close contact with the upper body 520a, whereby the processing space 502 is sealed from the outside. The lower body 520b has a first inlet 590 and an exhaust port 702. The upper body 520a has a second inlet 592. Supercritical fluid is supplied to the processing space 502 through the first inlet 590 and the second inlet 592. Further, the fluid in the processing space 502 is exhausted out of the drying chamber 500 through the exhaust port 702.

The first inlet 590 enables supercritical fluid to be supplied to the processing space 502 in the drying chamber 590 at a height lower than a substrate W in the drying chamber 500. The second inlet 592 enables supercritical fluid to be supplied to the processing space 502 in the drying chamber 590 at a height higher than a substrate W.

The first inlet 590 is coupled at a position departing from the center portion of the lower body 520b when seen from above. The exhaust port 702 is coupled to the center portion of the lower body 520b when seen from above. The second inlet 592 is coupled to the center portion of the upper body 520a when seen from above.

The drying chamber 500 equipped with heaters 570. According to an embodiment, the heaters 570 are positioned in the wall of the body 520. The heaters 570 heat the processing space 502 of the body 520 such that the fluid supplied into the processing space 502 of the body 520 maintains a supercritical state.

The supporting unit 540 supports a substrate W in the processing space 502 of the body 520. The supporting unit 540 has a fixing rod 542 and a holder 544. The fixing rod 542 is fixedly installed on the upper body 520a to protrude downward from the underside of the upper body 522a. The longitudinal direction of the fixing rod 542 is provided in the up-down direction. The fixing rod 542 is provided in multiple instances and the fixing rods 542 are positioned to be spaced apart from each other. The fixing rods 542 are disposed such that a substrate W does not interfere with the fixing rods 542 when the substrate W is loaded into or unloaded out of a space surrounded by the fixing rods 542. The holder 542 is coupled to each of the fixing rods 544. The holder 544 extends toward the space surrounded by the fixing rods 542 from the lower ends of the fixing rods 542. By the structure described above, the edge area of a substrate W loaded into the processing space 502 of the body 520 is placed on the holder 544, and the entire area of the top of the substrate W, the center area of the underside of the substrate W, and a portion of the edge area of the underside of the substrate W are exposed to supercritical fluid supplied into the processing space 502.

The fluid supply unit 560 supplies supercritical fluid into the processing space 502 of the body 520. In this case, supplying supercritical fluid means supplying fluid for processing a substrate W by changing the phase into a supercritical state. Accordingly, supplying supercritical fluid includes not only supplying fluid in a supercritical state directly into the processing space 502, but supplying fluid in a gas or subcritical state to the processing space 502 and phase change into a supercritical state in the processing space 502. In this embodiment, supercritical fluid is supplied to the processing space 502 in a supercritical state.

The detailed structure of the fluid supply unit is described below.

The filler 580 may be disposed in the processing space 502 in the body 520. The filler 580 is supported by a support 582 to be spaced upward apart from the underside of the body 520. A plurality of supports 582 is provided in a rod shape and the supports 582 are spaced a predetermined distance apart from each other. When seen from above, the filler 580 may be positioned to overlap the first inlet 590 and the exhaust port 702. The filler 580 can prevent processing fluid supplied through a first line 642 from being directly discharged toward a substrate W and damaging the substrate W. Further, the filler 580 can may the pressure in the processing space 502 rapidly increase by occupying the volume in the processing space 502 of the body 520.

The exhaust unit 700 includes an exhaust line 704. The exhaust line 704 is connected to the exhaust port 702. An exhaust valve 706 is installed in the exhaust line 704. The exhaust valve 706 opens and closes the exhaust line 704.

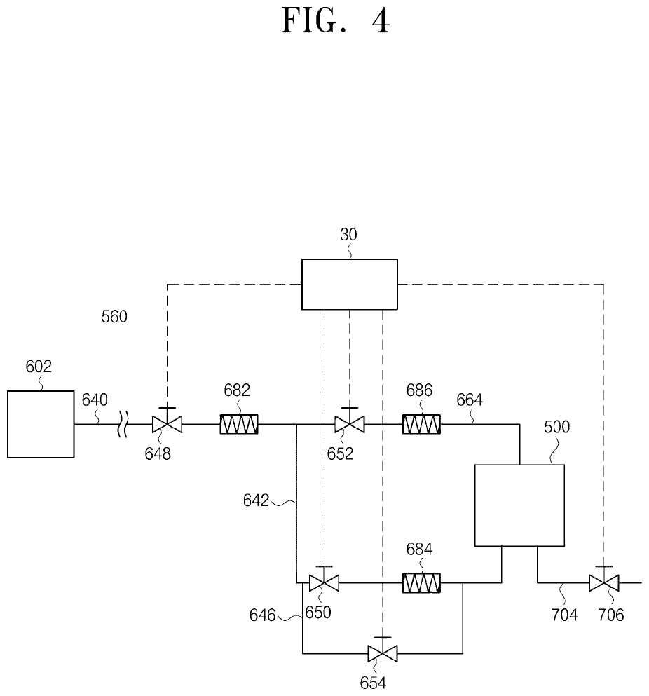

FIG. 4 is a view schematically showing an embodiment of a fluid supply unit.

The fluid supply unit 560 includes a fluid supplier 600, a fluid supply line 620, and a heating unit 680.

The fluid supplier 600 includes a supply tank 602. The supply tank 602 can store fluid in a supercritical state therein. According to an example, the fluid may be carbon dioxide.

The fluid supply line 560 includes a main supply line 640, a first line 6342, and a second line 644. The main supply line 640 is connected to the supply tank 602. The main supply line 640 branches into a first line 642 and a second line 644. The first line 642 connects the main supply line 640 and the first inlet 590 of the lower body 520b. The first line 642 supplies supercritical fluid to the processing space 502 at a lower position than a substrate W. The second line 644 supplies supercritical fluid to the processing space 502 at a higher position than a substrate W.

A main valve 648 is installed in the main supply line 640. The main valve 648 opens and closes the main supply line 640. A first valve 650 is installed in the first line 642. The first valve 650 opens and closes the first line 642. A second valve 652 is installed in the second line 644. The second valve 652 opens and closes the second line 644.

The heating unit 680 is installed in the fluid supply line 620 and heats the supercritical fluid flowing through the fluid supply line 620. The heating unit 680 has a main heater 682, a first heater 684, and a second heater 686.

The main heater 682 is installed in the main supply line 640. The main heater 682 may be installed at a downstream side further than the main valve 648. The first heater 684 is installed in the first line 642. The first heater 684 may be installed at a downstream side further than the first valve 650. The second heater 686 is installed in the second line 644. The second heater 686 is installed at a downstream side further than the second valve 652.

Further, the fluid supply line 620 may include a bypass line 646. The bypass line 646 is provided to bypass the first heater 684 in the first line 642. The bypass line 646 can diverge from the first line 642 at an upstream point further than the first valve 650 and can be connected back to the first line 642 at a downstream side further than the first heater 684.

The control unit 30 controls the transfer robot 320, the liquid treatment chamber 400, and the drying chamber 500 such that substrates can be processed in predetermined order.

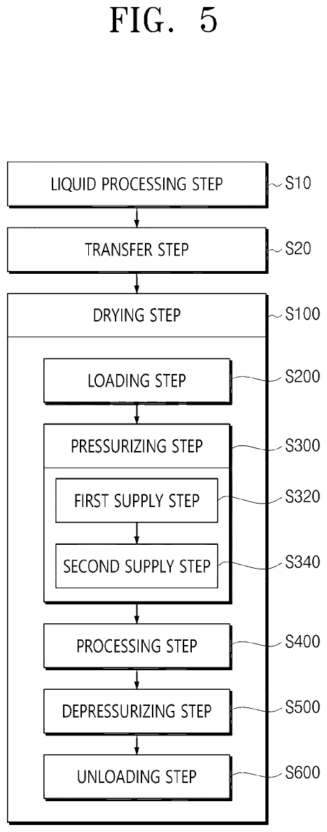

FIG. 5 is a flowchart schematically showing a substrate processing process.

Referring to FIG. 5, a liquid processing step S10, a transfer step S20, and a drying step S100 are sequentially performed on a substrate W. A chemical, pure water, and an organic solvent can be sequentially supplied to a substrate W in the liquid processing chamber 400. When liquid processing is finished, the substrate W is transferred to the drying chamber 500 by the transfer robot 320. The substrate W can be loaded into the drying chamber 500 with the organic solvent covering it. Thereafter, the substrate W is dried in the drying chamber 500. Hereafter, the drying processing process in the drying chamber 500 is described in detail.

The drying step S100 includes a loading step S200, a pressurizing step S300, a processing step S400, a depressurizing step S500, and an unloading step S600.

The main heater 682, the first heater 684, and the second heater 686 can be maintained in an On state during the drying step S100. According to an embodiment, the main heater 682 is set to heat supercritical fluid to a first temperature T1. The first heater 684 is set to heat supercritical fluid to a second temperature T2. The second heater 686 is set to heat supercritical fluid to a third temperature T3.

According to an example, the first temperature T1 may be temperature higher than critical temperature Tc. The second temperature T2 is temperature higher than the first temperature T1. The third temperature T3 is temperature higher than the first temperature T1. The third temperature T3 may be temperature higher than the second temperature T2.

The control unit 30 controls the opening/closing operation of the main valve 648, the first valve 650, the second valve 652, and the third valve 654 in each step.

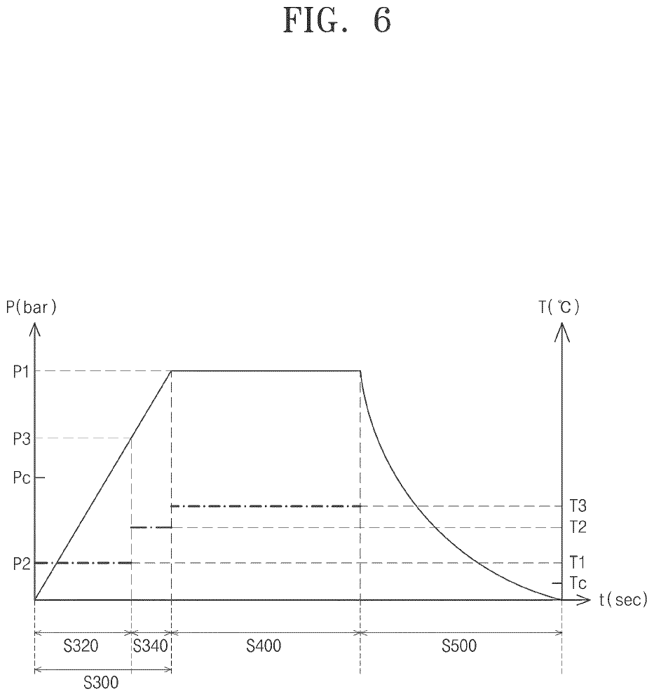

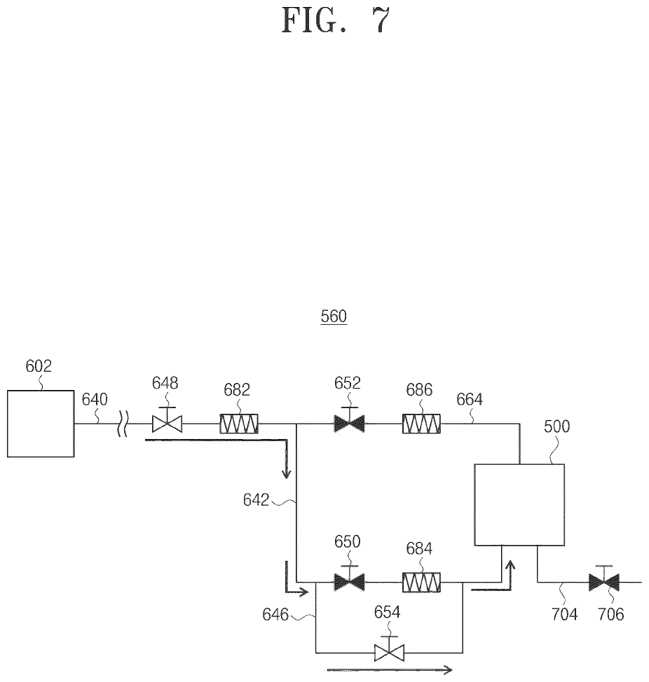

FIG. 6 is a graphs showing the pressure and temperature in the drying chamber over time in the drying step and, FIG. 7 to FIG. 10 are views showing the opening/closing state of valves in a first supply step, a second supply step, a processing step, and a depressurizing step.

The loading step S200 is performed first. In the loading step S200, the upper body 520a and the lower body 520b of the body 520 are spaced apart from each other and the transfer robot 320 loads a substrate W into the processing space 502. The substrate W in the processing space 502 is supported by the supporting unit 540. When the transfer robot 320 goes out of the processing space 502, the upper body 520a and the lower body 520b come in close contact with each other. While the loading step S200 is performed, the main valve 648, the first valve 650, the second valve 652, the third valve 654, and the exhaust valve 706 are all maintained in the closed state.

Thereafter, the pressurizing step S300 is performed. The processing space 502 is pressurized up to a first pressure P1 in the pressurizing step S300. The first pressure P1 may be pressure of the processing space 502 during the processing step S400. The pressurizing step S300 includes a first supply step S320 and a second supply step S340.

Referring to FIG. 6 and FIG. 7, in the first supply step S320, supercritical fluid flows through the supply tank 602, the main supply line 640, and the bypass line 646 of the first line 642 and is supplied to the processing space 502 through the first inlet 590. In the first supply step S320, the main valve 648 and the third valve 654 are opened, and the first valve 650, the second valve 652, and the exhaust valve 706 are closed. Accordingly, in the first supply step S320, supercritical fluid is supplied to the processing space 502 in a state heated to the first temperature T1. The first supply step S320 proceeds until the pressure of the processing space 502 reaches a third pressure P3. The third pressure P3 is pressure higher than the critical pressure Pc of supercritical fluid. When the pressure of the processing space 502 reaches the third pressure P3, the second supply step S340 is performed.

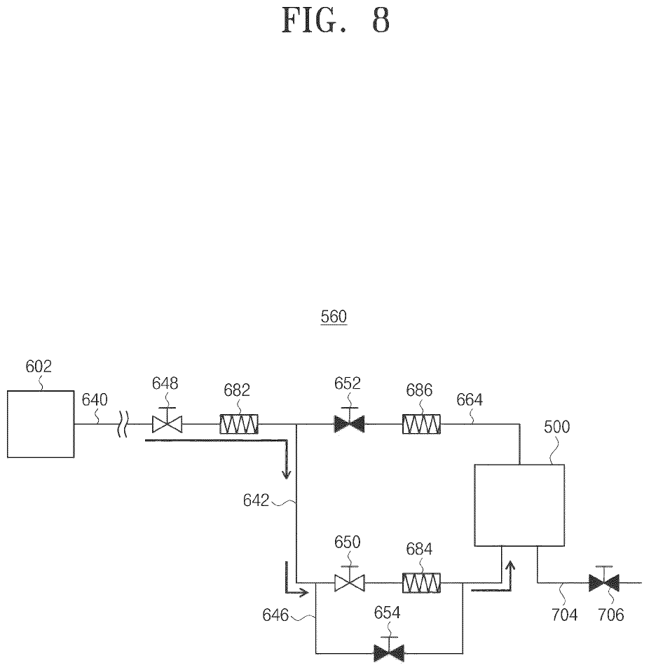

Referring to FIG. 6 and FIG. 8, in the second supply step S340, supercritical fluid flows through the supply tank 602, the main supply line 640, and the heater 684 of the first line 642 and is supplied to the processing space 502 through the first inlet 590. In the second supply step S340, the main valve 648 and the first valve 650 are opened, and the second valve 652, the third valve 654, and the exhaust valve 706 are closed. Accordingly, in the second supply step S340, supercritical fluid is supplied to the processing space 502 in a state heated to the second temperature T2. When the pressure of the processing space 502 reaches the first pressure P1, the processing step S400 is performed.

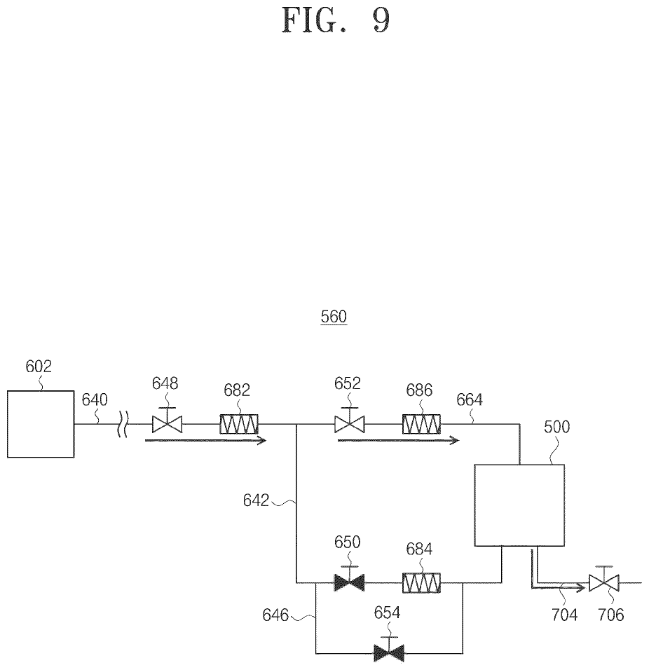

Referring to FIG. 6 and FIG. 9, in the processing step S400, supercritical fluid flows through the supply tank 602, the main supply line 640, and the second line 642 and is supplied to the processing space 502 through the second inlet 592. In the processing step S400, the main valve 648, the second valve 652, and the exhaust valve 706 are opened, and the first valve 650 and the third valve 654 are closed. Accordingly, in the processing step S400, supercritical fluid is supplied to the processing space 502 in a state heated to the third temperature T3. In the processing step S400, supercritical fluid is supplied through the second line 644 and simultaneously exhausted through the processing space 502 and the exhaust line 550. In the processing step S400, the amount of the supercritical fluid that is supplied to the processing space 502 and the amount of fluid that is exhausted from the processing space 502 may be the same or similar. Accordingly, in the processing step S400, the pressure in the processing space 502 is kept constant at the first pressure P1. When processing of the substrate W is finished in the processing step S400, the depressurizing step S500 is performed.

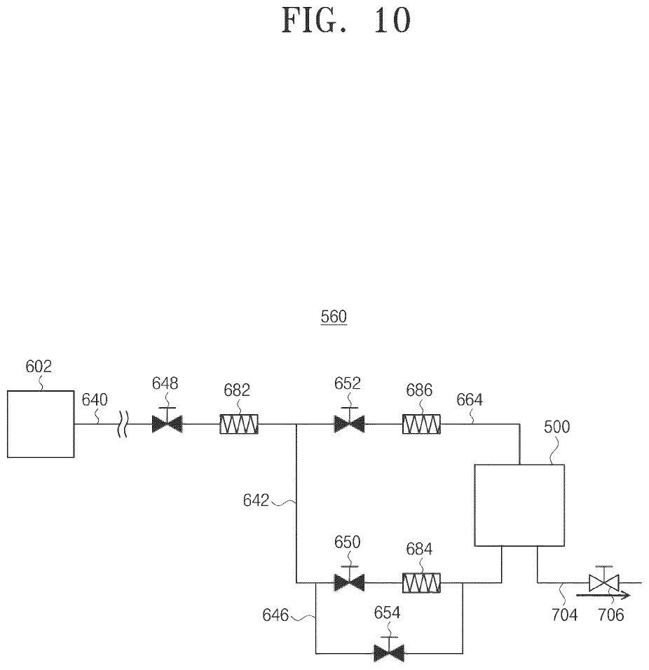

Referring to FIG. 6 and FIG. 10, in the depressurizing step S500, supercritical fluid is exhausted from the processing space 502 through the exhaust line 550. In the depressurizing step S500, the main valve 648, the first valve 650, the second valve 652, and the third valve 654 are closed, and the exhaust valve 706 is opened. Accordingly, the pressure in the processing space is decreased to the second pressure P2. For example, the second pressure P2 may be atmospheric pressure.

After the depressurizing step S500 is finished, the unloading step S600 is performed.

In the unloading step S600, the lower body 520b of the body 520 is moved downward, whereby the processing space 502 is opened. The transfer robot 320 enters the processing space and unloads the substrate W out of the processing space 502.

It was described in the embodiment of FIG. 6 that supply of supercritical fluid into the processing space 502 and exhaust of fluid from the processing space 502 are simultaneously and continuously performed in the processing step S400, so the pressure in the processing space 502 is kept constant. However, unlike this, in the processing step S400, supply of supercritical fluid into the processing space 502 and exhaust of fluid from the processing space 502 may be alternately repeated multiple times.

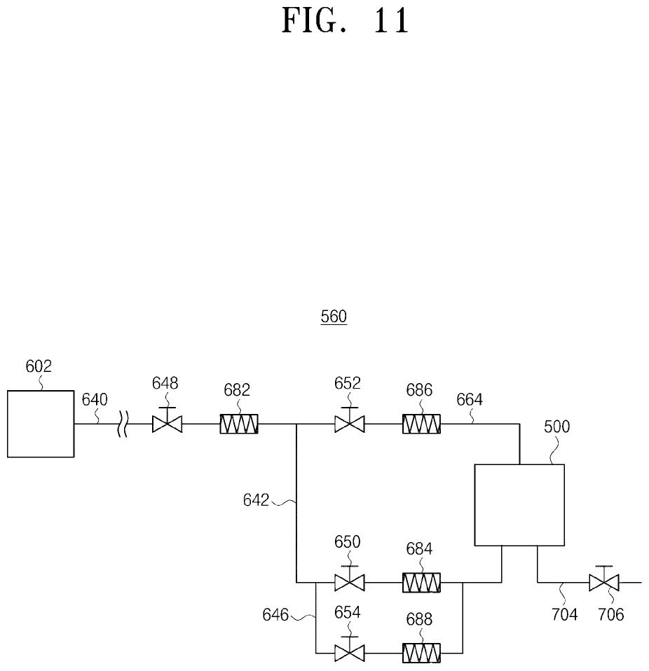

In the embodiment shown in FIG. 4, a heater is not provided in the bypass line 646. However, unlike this, as shown in FIG. 11, a third heater 688 may be installed in the bypass line 646. The third heater 686 may be set to heat supercritical fluid to a fourth temperature T4. The fourth temperature T4 may be temperature higher than the first temperature T1 and lower than the second temperature T2. In this case, in the first supply step S320, supercritical fluid can supplied to the processing space 502 in a state heated to the fourth temperature T4.

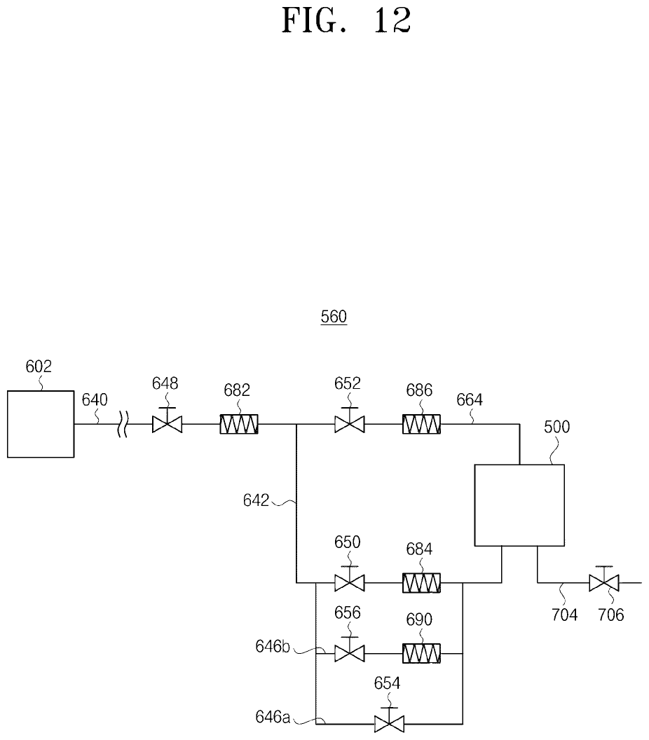

In the embodiment described above, the pressurizing step S300 is divided into two supply steps. However, unlike this, the pressurizing step S300 may have three or more supply steps. In this case, as shown in FIG. 12, the first line 642 may have a first bypass line 646a and a second bypass line 646b, and a fourth heater may be provided in the first bypass line 646a. In this case, the fourth heater 690 can heat supercritical fluid to a fifth temperature T5. The fifth temperature T5 may be temperature higher than the first temperature T1 and lower than the second temperature T2. A heater may not be provided in the second bypass line 646b. Selectively, a fifth heater (not shown) may be provided in the second bypass line 646b. The fifth heater (not shown) may be set to heat supercritical fluid to a sixth temperature T6. The sixth temperature T6 may be temperature higher than the first temperature T1 and lower than the fifth temperature T5.

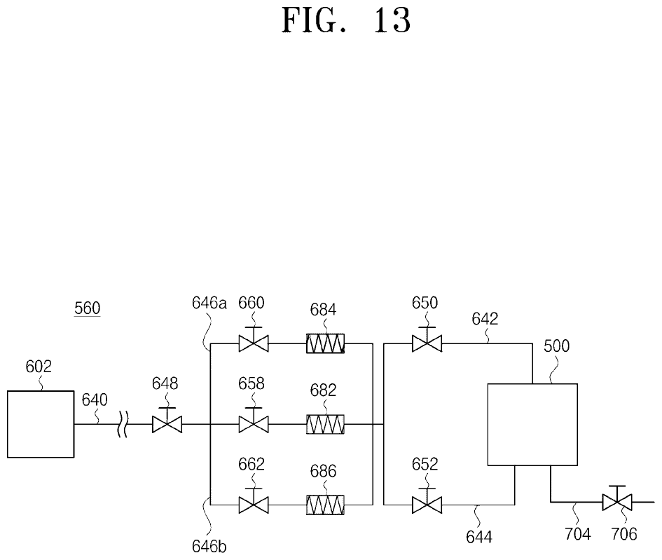

It was described in the example of FIG. 4 that the bypass line 646 is provided in the first line 642, so supercritical fluid is supplied through the bypass line 646 in the first supply step S320 and supercritical fluid is supplied through the first line 642 in the second supply step S340. However, as shown in FIG. 13, the bypass line 646 may not be provided in the first line 642 and the heating temperature of the second heater 686 may be adjusted to be different in the first supply step S320 and the second supply step S340.

It was described in the example of FIG. 4 that a heater is installed in each of the main supply line 640, the first line 642, and the second line 644. However, unlike this, as shown in FIG. 13, the first bypass line 646a and the second bypass line 646b that bypass the first heater 684 may be provided in the main supply line 640, and the second heater 686 and the third heater 688 of FIG. 4 may be installed in each of the bypass lines.

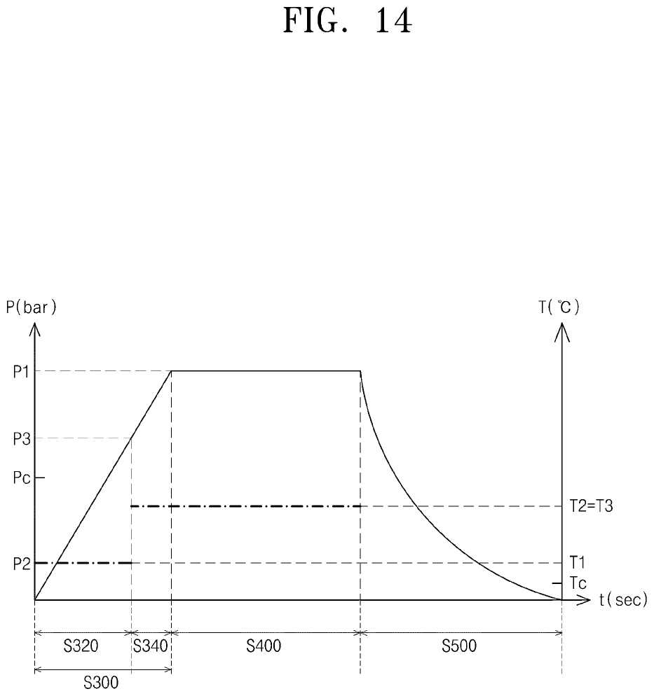

It was described with reference to FIG. 6 that the third temperature is higher than the second temperature. However, unlike this, as shown in FIG. 14, the third temperature T3 may be the same as the second temperature T2. That is, the supercritical fluid supply temperature in the processing step S400 and the supercritical fluid supply temperature in the second supply step S340 may be the same.

1. A substrate processing method, comprising:
a loading step of loading a substrate into a processing space;
a pressurizing step of pressurizing the processing space to a first pressure by supplying supercritical fluid to the processing space after the loading step;
a processing step of processing the substrate in the processing space by supplying the supercritical fluid to the processing space after the pressurizing step;
a depressurizing step of depressurizing the processing space to a second pressure lower than the first pressure after the processing step; and
an unloading step of unloading the substrate from the processing space after the depressurizing step,
wherein the pressurizing step comprises:
a first supply step of supplying the supercritical fluid at a first temperature to the processing space to a third pressure lower than the first pressure; and
a second supply step of supplying the supercritical fluid at a second temperature higher than the first temperature to the processing space when the pressure of the processing space reaches the third pressure.

2. The method of claim 1, wherein, in the processing step, the supercritical fluid is supplied to the processing space at a third temperature higher than the first temperature.

3. The method of claim 2, wherein the third temperature is the same as the second temperature.

4. The method of claim 2, wherein the third temperature is higher than the second temperature.

5. The method of claim 1, wherein the third pressure is higher than critical pressure of the supercritical fluid.

6. The method of claim 1, wherein a position of the supercritical fluid that is supplied to the processing space in the processing step and a position of the supercritical fluid that is supplied to the processing space in the pressurizing step are different from each other.

7. The method of claim 6, wherein, in the pressurizing step, the supercritical fluid is supplied to the processing space at a position lower than the substrate disposed in the processing space.

8. The method of claim 7, wherein, in the processing step, the supercritical fluid is supplied to the processing space at a position higher than the substrate disposed in the processing space.

9. The method of claim 1, wherein the supercritical fluid is carbon dioxide.

10. A substrate processing apparatus, comprising:
a body providing a processing space for processing a substrate;
a supporting unit supporting the substrate in the processing space;
a fluid supply unit supplying supercritical fluid to the processing space;
an exhaust unit exhausting fluid in the processing space; and
a control unit controlling the fluid supply unit,
wherein the fluid supply unit comprises:
a fluid supply line supplying supercritical fluid to the processing space from a fluid supplier; and
a heating unit installed in the fluid supply line and heating the supercritical fluid,
the control unit controls the fluid supply unit and the exhaust unit such that a pressurizing step of pressurizing the processing space to a first pressure by supplying supercritical fluid to the processing space when a substrate is loaded into the processing space, a processing step of processing the substrate in the processing space using the supercritical fluid supplied to the processing space after the pressurizing step, and a depressurizing step of depressurizing the processing space to a second pressure lower than the first pressure are sequentially performed, and
the control unit controls the fluid supply unit such that a first supply step of supplying the supercritical fluid at a first temperature to the processing space to a third pressure lower than the first pressure in the pressurizing step, and a second supply step of supplying the supercritical fluid at a second temperature higher than the first temperature to the processing space when the pressure of the processing space reaches a set temperature are sequentially performed.

11.-19. (canceled)

20. A substrate processing method, comprising:
a liquid processing step of liquid-processing a substrate by supplying a processing liquid to the substrate in a liquid processing chamber;
a transfer step of transferring the substrate into a drying chamber after the liquid processing step; and
a drying step of drying the substrate using supercritical fluid in the drying chamber after the transferring step,
wherein the drying step comprises:
a loading step of loading a substrate into a processing space provided in the drying chamber;
a pressurizing step of pressurizing the processing space to a first pressure by supplying supercritical fluid to the processing space after the loading step;
a processing step of processing the substrate in the processing space using the supercritical fluid supplied to the processing space after the pressurizing step;
a depressurizing step of depressurizing the processing space to a second pressure lower than the first pressure after the processing step; and
an unloading step of unloading the substrate from the processing space after the depressurizing step,
wherein the pressurizing step comprises a first supply step and a second supply step,
wherein the pressurizing step comprises:
a first supply step of supplying the supercritical fluid at a first temperature to the processing space at a height lower than the substrate to a third pressure lower than the first pressure; and
a second supply step of supplying the supercritical fluid at a second temperature higher than the first temperature to the processing space at a height higher than the substrate when the pressure of the processing space reaches the third pressure,
the supercritical fluid is supplied at a third temperature to processing space in the processing step, and
the third temperature is higher than the first temperature and is the same as or higher than the second temperature.
